(19) United States
(12) Patent Application Publication
(10) Pub. No.: US 2025/0034750 A1
(43) Pub. Date: Jan. 30, 2025

(54) METAL OXIDE MANUFACTURING DEVICE AND METAL OXIDE MANUFACTURING METHOD

(71) Applicant: DIC Corporation, Tokyo (JP)

(72) Inventors: Hideyuki MURATA, Chiba (JP); Naoto YAGI, Chiba (JP); Masaki IIDA, Chiba (JP); Shoji IMAMURA, Chiba (JP); Jianjun YUAN, Chiba (JP)

(21) Appl. No.: 18/709,177

(22) PCT Filed: Nov. 8, 2022
(86) PCT No.: PCT/JP2022/041527

§ 371 Date: May 10, 2024

(30) Foreign Application Priority Data
Nov. 10, 2021 (JP) 2021-183370

(51) Int. Cl. C30B 19/02; C30B 29/16

(52) U.S. Cl. CPC C30B 19/02; C30B 29/16

(57) ABSTRACT

A manufacturing device includes a first gas inlet that is disposed closer to a first end of a firing furnace and introduces gas into the firing furnace, a gas outlet that is disposed closer to a second end of the firing furnace and discharges gas inside the firing furnace to the outside, and a transport device that transports a metal compound and a flux from a point closer to the gas outlet to a point closer to the first gas inlet. The firing furnace has a heating region, a cooling region, and a reaction region that is defined between the heating region and the cooling region and in which the metal compound and the flux react. The manufacturing device utilizes airflow generated by the gas introduced through the first gas inlet to convert the flux vaporized in the reaction region into powder in the cooling region and to deliver gas containing the powder of the flux to the gas outlet.

### TECHNICAL FIELD

The present invention relates to a metal oxide manufacturing device and a metal oxide manufacturing method. The present application claims priority based on Japanese Patent Application No. 2021-183370, filed in Japan on Nov. 10, 2021, the contents of which are incorporated by reference herein.

### BACKGROUND ART

In recent years, studies on the synthesis of inorganic materials inspired by nature and living organisms have been actively ongoing. The flux method was developed through such studies, drawing upon the wisdom of the natural world in the formation of crystals (minerals). In the flux method, crystals are precipitated out from a solution of an inorganic compound or metal at a high temperature. Advantages of the flux method include crystal growth temperatures much lower than the melting point of the desired crystals, minimal defects in the resulting crystals, and idiomorphic development.

Known techniques for manufacturing a metal oxide by the flux method include (1) flux annealing and (2) flux evaporation method. In the presence of a suitable oxide or salt serving as a flux, a metal compound precursory to the metal oxide is fired at a high temperature and then (1) slowly cooled or (2) evaporated. Whereas the flux annealing is a technique in which a supersaturated state created during slow cooling promotes the growth of metal oxide crystals, the flux evaporation method is a technique in which the evaporation of the flux is used as a driving force for promoting the growth of metal oxide crystals. The flux evaporation method offers benefits because of the evaporation of the flux away from the firing vessel; for example, it requires no troublesome work, such as flux removal through cleaning, unlike the flux annealing.

Requiring no troublesome work, flux evaporation method is commonly used in the manufacture of metal oxides. For example, PTL 1 describes an invention relating to a process for producing an artificial corundum crystal in which an artificial corundum crystal having a hexagonal-bipyramidal basic shape is produced by a flux evaporation method method that involves heating a sample containing a raw material and a flux and inducing the precipitation and growth of crystals using the evaporation of the flux as a driving force.

Incidentally, the manufacture of metal oxides by flux evaporation method has drawbacks such as great environmental impact and high manufacturing cost; because of the nature of the method using the evaporation of a flux as a driving force, the evaporated flux is released out of the instrument system/into the environment.

To solve this problem, a production apparatus has been disclosed by the applicant of the present invention that includes a firing furnace that fires a metal compound in the presence of a flux, a cooling pipe that is connected to the firing furnace and converts the flux vaporized through the firing into powder, and a recovery means that collects the flux converted into powder in the cooling pipe (PTL 2). This production apparatus converts the flux that evaporates out of the firing furnace into powder, primarily in the cooling pipe, and collects the powder of the flux at a dust collector. The collected flux can be recycled for the production of the metal oxide, allowing for reductions in environmental impact and manufacturing cost.

### CITATION LIST

### Patent Literature

PTL 1: International Publication No. 2005/054550

PTL 2: Japanese Patent No. 6455747

### SUMMARY OF INVENTION

### Technical Problem

For this known production apparatus, the cooling pipe includes a vertical pipe through which the gas inside the firing furnace is discharged, a horizontal pipe having a gas inlet port at one end with the other end connected to the recovery means, and a communication section at which the vertical and horizontal pipes intersect and communicate. When a metal oxide, such as molybdenum oxide (MoO₃), is produced using this production apparatus, the powder of the flux (molybdenum compound) adheres to the inner walls of the communication section, the inner walls of the vertical pipe in particular. In certain cases, the constriction of the inside of the communication section by the adhering flux makes it difficult to maintain appropriate flow passages. One countermeasure against it is the method of installing a scraper or similar jig in the cooling pipe and regularly removing the adhering flux with it. This method, however, has the disadvantage of the corrosion of the jig by molybdenum oxide because the gas discharged from the firing furnace contains molybdenum oxide. Another is the method of placing a heat-insulating sleeve inside the vertical pipe and preventing the reaction between the vaporized flux coming from the firing furnace and the vertical pipe with it. In this case, too, the heat-insulating sleeve is corroded by molybdenum oxide because it is exposed to gas containing molybdenum oxide.

An object of the present invention is to provide a metal oxide manufacturing device and a metal oxide manufacturing method with which the flux can be collected in a stable manner and that require no installation of jigs or components for maintenance, helping reduce maintenance efforts significantly.

### Solution to Problem

To achieve the above object, the present invention provides the following means.
[1] A device for manufacturing a metal oxide by flux evaporation method, the device including:
a firing furnace that fires a metal compound in presence of a flux;
a first gas inlet that is disposed closer to a first end of the firing furnace and introduces gas into the firing furnace; a gas outlet that is disposed closer to a second end of the firing furnace and discharges gas inside the firing furnace to outside; and
a transport device that is placed inside the firing furnace and transports the metal compound and the flux or a metal oxide obtained through reaction therebetween from a point closer to one of the first gas inlet or the gas outlet to a point closer to the other, wherein:
the firing furnace has a heating region defined closer to one of the gas outlet or the first gas inlet, a cooling region defined closer to the other of the gas outlet or the first gas inlet, and a reaction region that is defined between the heating region and the cooling region, in which temperature is higher than in both of the heating region and the cooling region, and in which the metal compound and the flux react; and
with use of airflow generated by the gas introduced through the first gas inlet, the flux vaporized in the reaction region is converted into powder in the heating region or the cooling region, and gas containing the powder of the flux is delivered to the gas outlet.
[2] The device according to [1] above for manufacturing a metal oxide, wherein:
the heating region is defined closer to the gas outlet, and the cooling region is defined closer to the first gas inlet;
the airflow is countercurrent with respect to a direction of transport by the transport device and passes through the cooling region, the reaction region, and the heating region in this order; and
the flux vaporized in the reaction region is converted into powder in the heating region.
[3] The device according to [1] above for manufacturing a metal oxide, wherein:
the heating region is defined closer to the first gas inlet, and the cooling region is defined closer to the gas outlet;
the airflow is co-current with respect to a direction of transport by the transport device and passes through the heating region, the reaction region, and the cooling region in this order; and
the flux vaporized in the reaction region is converted into powder in the cooling region.
[4] The device according to [3] above for manufacturing a metal oxide, wherein a vapor of the metal oxide obtained from the metal compound and the flux that are transported by the transport device and located upstream, with respect to the direction of transport, of the reaction region is supplied to the metal compound and the flux located downstream of the reaction region.
[5] The device according to [3] or [4] above for manufacturing a metal oxide, further including a second gas inlet that is disposed at the cooling region in the firing furnace and supplies gas to the airflow that passes through the cooling region.
[6] The device according to any of [1] to [5] above for manufacturing a metal oxide, wherein the gas outlet includes a main duct through which the gas inside the firing furnace is discharged out of the furnace and a third gas inlet that is provided to the main duct and through which gas is supplied from outside to the gas containing the powder of the flux that flows through the main duct.
[7] The device according to any of [1] to [6] above for manufacturing a metal oxide, wherein the firing furnace includes an anticorrosive heat insulator attached to an inner surface of the firing furnace.
[8] The device according to [1] above for manufacturing a metal oxide, including a collection device that is coupled to the gas outlet and collects the powder of the flux contained in the gas.
[9] The device according to [8] above for manufacturing a metal oxide, wherein the collection device includes a dust collector that collects the powder of the flux.
[10] The device according to [9] above for manufacturing a metal oxide, wherein the collection device further includes a classifier that is disposed between the gas outlet and the dust collector and classifies the powder of the flux.
[11] A method for manufacturing a metal oxide by flux evaporation method, the method including:
introducing gas into a firing furnace, the firing furnace configured to fire a metal compound in presence of a flux, through a gas inlet disposed closer to a first end of the firing furnace and discharging gas inside the firing furnace to outside through a gas outlet disposed closer to a second end of the firing furnace;
transporting, inside the firing furnace, the metal compound and the flux or a metal oxide obtained through reaction therebetween from a point closer to one of the gas inlet or the gas outlet to a point closer to the other; and
defining, in the firing furnace, a heating region closer to one of the gas outlet or the gas inlet, a cooling region closer to the other of the gas outlet or the gas inlet, and a reaction region between the heating region and the cooling region, with the reaction region being a region in which temperature is higher than in both of the heating region and the cooling region and in which the metal compound and the flux react, and, with use of airflow generated by the gas introduced through the gas inlet, converting the flux vaporized in the reaction region into powder in the heating region or the cooling region and delivering gas containing the powder of the flux to the gas outlet.

### Advantageous Effects of Invention

According to the present invention, there are provided a metal oxide manufacturing device and a metal oxide manufacturing method with which the flux can be collected in a stable manner and that require no installation of jigs or components for maintenance, helping reduce maintenance efforts much more.

### BRIEF DESCRIPTION OF DRAWINGS

FIG. 1 is a schematic view illustrating an example of a metal oxide manufacturing device according to this embodiment.

FIG. 2 is a schematic view illustrating regions in the firing furnace in FIG. 1.

FIG. 3 is a schematic view illustrating a variation of a metal oxide manufacturing device according to this embodiment.

FIG. 4 is a schematic view illustrating another variation of a metal oxide manufacturing device according to this embodiment.

FIG. 5 is a schematic view illustrating another variation of a metal oxide manufacturing device according to this embodiment.

FIG. 6 is a schematic view illustrating another variation of a metal oxide manufacturing device according to this embodiment.

### DESCRIPTION OF EMBODIMENTS

An embodiment of the present invention will now be described in detail with reference to drawings.

It should be noted that in the drawings used in the following description, the scale of dimensions may vary from element to element for easier recognition of each structural element; the relative dimensions, for example, of the individual elements is not necessarily the same as the reality. The structures, materials, and other details presented by way of example in the following description, furthermore, are for illustrative purposes; the present invention is not necessarily limited to them and can be implemented with modifications within the gist of the invention.

### Metal Oxide Manufacturing Device

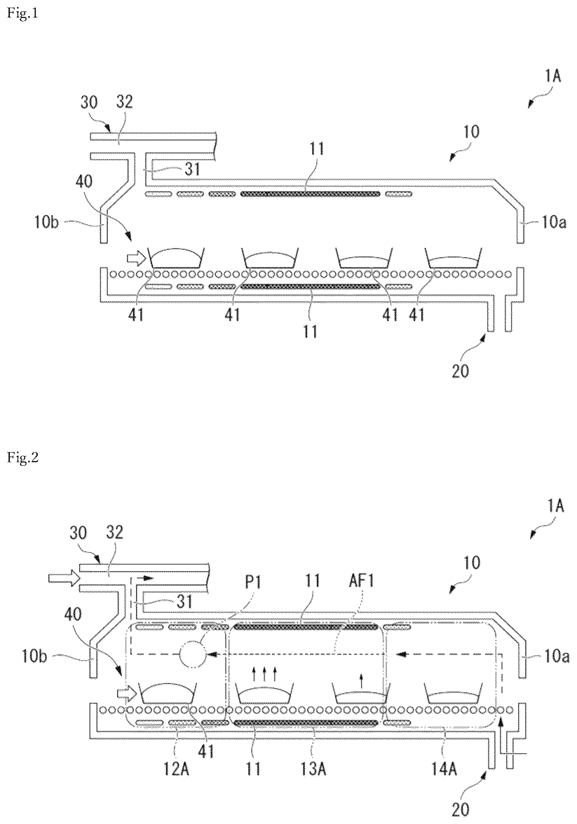

FIG. 1 is a schematic view illustrating an example of a metal oxide manufacturing device according to this embodiment. The manufacturing device in FIG. 1 is a device for manufacturing a metal oxide by flux evaporation method. Flux evaporation method is a method in which a metal oxide is manufactured by firing at least one metal compound in the presence of at least one flux. During the firing process, the flux evaporates, and the growth of metal oxide crystals proceeds utilizing the flux evaporation method as a driving force.

As illustrated in FIG. 1, the metal oxide manufacturing device 1A includes a firing furnace 10 that fires at least metal compound in the presence of at least one flux, at least one first gas inlet 20 that is disposed closer to a first end 10a of the firing furnace 10 and introduces gas into the firing furnace 10, a gas outlet 30 that is disposed closer to a second end 10b of the firing furnace 10 and discharges gas inside the firing furnace 10 to the outside, and a transport device 40 that is placed inside the firing furnace 10 and transports the metal compound and the flux or a metal oxide obtained through the reaction therebetween from a point closer to the gas outlet 30 to a point closer to the first gas inlet 20.

The firing furnace 10 in this embodiment is typically a continuous firing furnace because it allows for easier creation of a high-temperature region and a low-temperature region inside the furnace and because it enables mass production by supporting continuous feeding of raw materials into the firing furnace. Examples of continuous firing furnaces include, although not particularly restricted, a continuous rotary kiln firing furnace, a roller hearth kiln furnace, a pusher furnace, a conveyor furnace, a net conveyor furnace, a shaft kiln furnace, and a fluidized firing furnace. Of these, it is more preferred that the firing furnace be a roller hearth kiln furnace, pusher furnace, conveyor furnace, or net conveyor furnace, even more preferably a roller hearth kiln furnace or pusher furnace.

Examples of heating mechanisms for the firing furnace 10 include, although not particularly restricted, electricity, gas, microwaves, and infrared radiation. Of these, it is preferred that the heating mechanism be electric heating because of its ease of industrialization and controllability. In this embodiment, there are heaters 11 inside the firing furnace 10, and the heaters 11 have been positioned on the top wall and bottom wall of the firing furnace 10. The heaters 11 may be positioned on one of the top wall or bottom wall of the firing furnace 10.

The firing furnace 10 has, for example, a longitudinal direction parallel to the direction of transport by the transport device 40 (the direction of the arrow in FIG. 1) and a direction perpendicular to the longitudinal direction (also referred to as the transverse or horizontal direction) in plan view. In this embodiment, the first end 10a of the firing furnace 10 is one end in the longitudinal direction, and the second end 10b of the firing furnace 10 is the other end in the longitudinal direction.

The first gas inlet 20 is preferably positioned on the side opposite where the gas outlet 30 is installed because this allows for efficient discharge of the powder of the flux from the firing furnace. In this embodiment, the first gas inlet 20 is positioned closer to the second end 10a of the firing furnace, which is opposite the first end 10b, near which the gas outlet 30 is installed.

To ensure efficient generation of airflow from the first gas inlet 20 toward the gas outlet 30 throughout the inside of the firing furnace 10, furthermore, it is preferred that the first gas inlet 20 be disposed in the bottom wall or a lower portion of a side wall of the firing furnace 10. One first gas inlet 20 may be provided to the firing furnace 10, or two or more may be provided.

When two or more first gas inlets 20 are provided to the firing furnace 10, moreover, the first gas inlets 20 may include one or multiple primary inlets for generating airflow AF1, which will be described later herein, inside the firing furnace 10 and multiple secondary inlets disposed at regular intervals in the bottom of the firing furnace 10 for generating airflow from lower to upper spaces inside the firing furnace 10.

The gas introduced through the first gas inlet 20 is not particularly restricted as long as it has no reactivity with the flux vapor, but examples include air (in that case, a gas intake port is also referred to as an “external air intake port”), oxygen, nitrogen, argon, and steam. Of these, it is preferred that the gas be air for cost reasons.

The first gas inlet 20 may include a first blowing device, not illustrated, that forces the gas into the firing furnace 10. This ensures that sufficient airflow from the reaction region toward the heating region, both described later herein, will be generated inside the firing furnace 10 and, at the same time, allows the flux converted into powder inside the firing furnace 10 to be discharged out of the firing furnace successfully. Specifically, when the gas is forced into the firing furnace 10, unidirectional airflow is generated inside the firing furnace 10, facilitating the movement of the gas inside the firing furnace 10 (containing the powder of the flux) to the gas outlet 30 compared with when the gas is not forced into the firing furnace 10. The powder of the flux, therefore, can be collected quickly and effectively. In flux evaporation method, furthermore, the evaporation of the flux is a driving force for crystal growth, which means that facilitating the movement of the vaporized flux from the reaction region to the heating region, both described later herein, can lead to smooth progress of the flux evaporation method process. As a result, the resulting metal oxide crystals can be well-grown ones.

The first gas inlet 20 may include a throttle damper, not illustrated, that regulates the quantity, velocity, etc., of the gas introduced into the firing furnace. The throttle damper is not particularly restricted and can be a known one. The throttle damper may have a motor, may have a non-return mechanism, and may have a slit. The first gas inlet 20, furthermore, may include one throttle damper or may include two or more, depending on the configuration of the firing furnace.

The gas outlet 30 discharges gas containing the powder of the flux to the outside of the firing furnace 10. The gas outlet 30 includes, for example, a main duct 31 through which gas inside the firing furnace 10 is discharged out of the furnace and a third gas inlet 32 that is provided to the main duct 31 and through which gas is supplied from the outside to the gas that flows through the main duct 31. The gas outlet 30 includes, for example, a T-shaped pipe, with the main duct 31 formed by an L-shaped portion and the third gas inlet 32 formed by an I-shaped portion communicating with the L-shaped portion. Shaping the gas outlet 30 in such a shape ensures that the introduced external gas travels straight for transport to a dust collector, which will be described later herein, thereby allowing for a swift transition to the collection step. As a result, it can become possible to collect large-diameter particles of the flux with little aggregation therebetween.

The material for the pipes that form the gas outlet 30 is not particularly restricted; known metals and alloys can be used.

The gas introduced through the third gas inlet 32 is not particularly restricted as long as it has no reactivity with the flux vapor, but examples include air (in that case, a gas intake port is herein also referred to as an “external air intake port” in particular), oxygen, nitrogen, argon, and steam. Of these, it is preferred the gas be air for cost reasons.

The gas outlet 30 may include a second blowing device, not illustrated, that is provided to the third gas inlet 32 and forces air into the gas outlet 30. The negative pressure generated by the gas introduced through the third gas inlet facilitates the movement of the gas containing the powder of the flux inside the firing furnace 10 to the gas outlet 30. With the blowing device, furthermore, the flux-containing gas can be further cooled outside the firing furnace 10 considering, for example, the flux temperature at the time of the downstream collection. As a result, particles of the flux with uniform diameters and little or reduced aggregation therebetween can be collected.

The third gas inlet 32 may include a throttle damper, not illustrated, that regulates the quantity, velocity, etc., of the gas introduced into the firing furnace. The throttle damper is not particularly restricted and can be a known one. The throttle damper may have a motor, may have a non-return mechanism, and may have a slit. The third gas inlet 32, furthermore, may include one throttle damper or may include two or more, depending on the configuration of the firing furnace.

The transport device 40 includes, for example, a transport unit and a driving unit that drives the transport unit. By mounting a container 41 on the transport unit and operating the driving unit to drive the transport unit, the transport device 40 transports the container 41 inside the firing furnace 10. The transport unit is not particularly restricted and can be equipment such as rollers, a baseplate, or a trolley. The container 41 mounted on the transport unit is, for example, a firing container called saggar. The container 41 contains the reactants (the metal compound and the flux) upstream of the reaction region, which will be described later herein, and contains the product (the metal oxide obtained through the reaction between the metal compound and the flux) downstream of the reaction region, both with respect to the direction of transport by the transport device 40.

In this embodiment, the first gas inlet 20 is disposed closer to the first end 10a of the firing furnace 10, and the gas outlet 30 is disposed closer to the second end 10b. The transport device 40, furthermore, brings a container 41 containing the reactants into the firing furnace 10 from near the first end 10b of the firing furnace 10 and takes out the container 41 containing the product from near the first end 10a of the firing furnace 10.

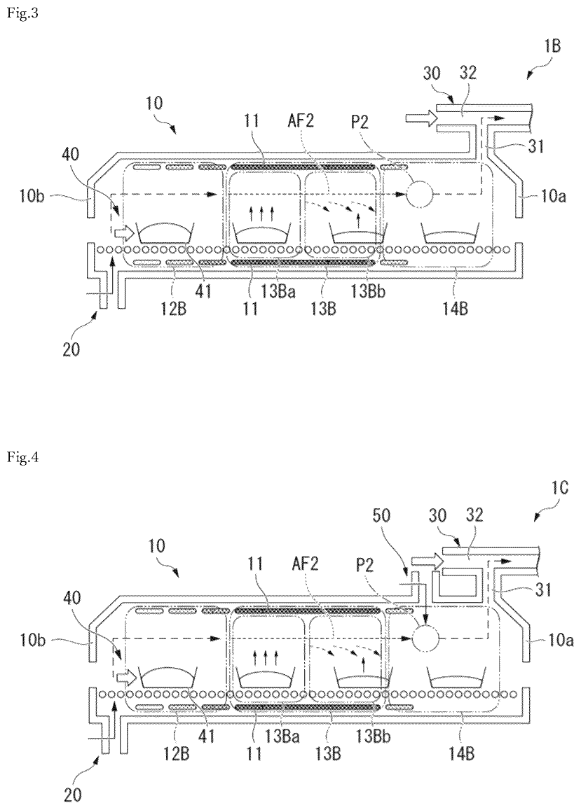

FIG. 2 is a schematic view illustrating regions in the firing furnace 10 in FIG. 1.

As illustrated in FIG. 2, the firing furnace 10 has a heating region 12A defined closer to the gas outlet 30, a cooling region 14A defined closer to the first gas inlet 20, and a reaction region 13A that is defined between the heating region 12A and the cooling region 14A, in which the temperature is higher than in both of the heating region 12A and the cooling region 14A, and in which the metal compound and the flux react.

The heating region 12A is a region in which the container 41 and the reactants in the container 41 transported into the firing furnace 10 are heated. The heating region 12A has a temperature gradient in which the temperature increases with proximity to the reaction region 13A with respect to the direction of transport. There are heaters 11 installed in the heating region 12A, and the heaters 11 are controlled in such a manner that the region will have this temperature gradient.

The heating region 12A is positioned, for example, downstream of the gas outlet 30 with respect to the direction of transport by the transport device 40. In other words, the heating region 12A is positioned upstream of the gas outlet 30 with respect to the direction of airflow AF1, which will be described later herein.

The reaction region 13A is a region in which the reactants in the container 41 transported from the heating region 12A are allowed to react. The reaction region 13A is not particularly restricted as long as the temperature in it is higher than in both of the heating region 12A and the cooling region 14A. By way of example, however, it has no substantial temperature gradient with respect to the direction of transport and has almost constant temperatures with respect to the direction of transport. The reaction region 13A, furthermore, may have a stepwise or continuous temperature gradient with respect to the direction of transport, with the proviso that the temperature in it is higher than in both of the heating region 12A and the cooling region 14A. There are heaters 11 installed in the reaction region 13A, and the heaters 11 are controlled in such a manner that the region will have the aforementioned constant temperatures.

The cooling region 14A is a region in which the container 41 and the product in the container 41 transported from the reaction region 13A are cooled. This heating region 12A has a temperature gradient in which the temperature decreases with distance from the reaction region 13A with respect to the direction of transport. There are heaters 11 installed in part of the reaction region 13A, and the heaters 11 are controlled in such a manner that the region will have this temperature gradient. The cooling region 14A may have heaters 11 installed in part of it or may have no heaters 11.

The boundary between the heating region 12A and the reaction region 13A and the boundary between the reaction region 13A and the cooling region 14A cannot be clearly established. By way of example, however, the region inside the firing furnace 10 in which the temperature is maintained sufficiently high for the intermediate resulting from the reaction between the flux and the metal compound to decompose can be considered the reaction region 13A, the region upstream, with respect to the direction of transport, of the reaction region 13A (closer to the inlet for the container 41) can be considered the heating region 12A, and the region downstream of the reaction region 13A (closer to the outlet for the container 41) can be considered the cooling region 14A. As for the temperature in each region, the respective temperature distributions in the heating region 12A, reaction region 13A, and cooling region 14A, for example, may be measured, and the average temperature in each temperature distribution may be determined. Alternatively, the respective temperatures in the heating region 12A, reaction region 13A, and cooling region 14A may be measured in the middle of each region with respect to the direction of transport. Examples of measured temperatures in each region include the temperatures of the heaters themselves in each region and one or multiple atmospheric temperatures near the heaters measured using thermocouples.

In this embodiment, the heating region 12A has been defined closer to the second end 10b of the firing furnace 10, and the cooling region 14A has been defined closer to the first end 10a of the firing furnace 10. The container 41 passes through the cooling region 14A, reaction region 13A, and heating region 12A inside the firing furnace 10 and is transported in this order.

The metal oxide manufacturing device 1A, configured as described above, utilizes airflow AF1 generated by the gas introduced through the first gas inlet 20 to convert the flux vaporized in the reaction region 13A into powder in the cooling region 14A and to deliver gas containing the powder of the flux to the gas outlet 30. As this indicates, in this embodiment, furnace annealing is employed to convert the vaporized flux into powder inside the firing furnace 10.

In this embodiment, furthermore, the airflow AF1 is countercurrent with respect to the direction of transport, described earlier herein, and passes through the cooling region 14A, reaction region 13A, and heating region 12A in this order. Additionally, the airflow AF1 converts the flux vaporized in the reaction region 13A into powder in the heating region 12A. In this embodiment, therefore, the heating region 12A functions as a region in which the metal compound and the flux, which are the reactants, are heated and in which the flux is converted into powder through the cooling of gas containing the vaporized flux at the same time. In the example in FIG. 2, the vaporized flux is converted into powder at a point P1 that is on the airflow AF1 and above the transport device 40 (upper portion of the heating region 12A).

Moreover, in this embodiment, the gas introduced through the first gas inlet 20 cools the container 41 in the cooling region 14A, and, at the same time, the gas that has passed through the cooling region 14A and the reaction region 13A heats the container 41 in the heating region 12A. This leads to efficient cooling of the container 41 and the product in the container 41 in the cooling region 14A and efficient heating of the container 41 and the reactants in the container 41 in the heating region 12A.

### Metal Oxide Manufacturing Method

A metal oxide manufacturing method according to this embodiment is a method for manufacturing a metal oxide by flux evaporation method and includes the following steps (1) to (3). The order of steps (1) to (3) is not particularly restricted and can be changed within the gist of the present invention. The method, furthermore, may include one or multiple other steps before step (1), after step (3), or between two steps.

An example of a metal oxide manufacturing method according to this embodiment will now be described with reference to the metal oxide manufacturing device in FIG. 2. The metal oxide manufacturing method according to this embodiment does not need to be conducted with the metal oxide manufacturing device in FIG. 2 and can be performed with other metal oxide manufacturing devices.

### Step (1)

In step (1), gas is introduced into a firing furnace through a first gas inlet disposed closer to a first end of the firing furnace, the firing furnace configured to fire at least one metal compound in the presence of at least one flux, and gas inside the firing furnace is discharged to the outside through a gas outlet disposed closer to a second end of the firing furnace. For instance, in the example in FIG. 2, gas is introduced into the firing furnace 10 through the first gas inlet 20, disposed closer to the first end 10a of the firing furnace 10, and gas inside the firing furnace 10 is discharged to the outside through the gas outlet 30, disposed closer to the second end 10b of the firing furnace 10.

For the gas introduced through the first gas inlet, examples include air, oxygen, nitrogen, argon, and steam. Of these, it is preferred that the gas be air when cost is considered.

When the gas is blown into the firing furnace through the first gas inlet, the temperature of the gas blown is preferably 5° C. or above, more preferably 10° C. or above.

The rate of blowing of the gas, furthermore, is preferably from 1 to 500 L/minute, more preferably from 10 to 200 L/minute, per 100 L of the effective volume of the firing furnace.

The internal pressure of the firing furnace is not particularly restricted; it may be a positive pressure or negative pressure and can be from −5000 to +1000 Pa. For successful discharge of the flux from the firing furnace into a cooling pipe, furthermore, it is preferred that the firing be conducted under reduced pressure. To give specific examples for the degree of pressure reduction, the pressure can be from −5000 to −10 Pa, from −2000 to −20 Pa, or from −1000 to −50 Pa.

### Flux

Examples of fluxes include, although not particularly restricted, molybdenum compounds, tungsten compounds, vanadium compounds, chlorine compounds, fluorine compounds, boron compounds, sulfates, nitrates, and carbonates.

For the molybdenum compounds, examples include, although not particularly restricted, metallic molybdenum, molybdenum trioxide, molybdenum dioxide, molybdenum sulfide, ammonium molybdate, H₃PMo₁₂O₄₀, H₃SiMo₁₂O₄₀, K₂MoₙO₃ₙ₊₁ (n=1 to 3), Na₂MoₙO₃ₙ₊₁ (n=1 to 3), Li₂MonO₃ₙ₊₁ (n=1 to 3), MgMoₙO₃ₙ₊₁ (n=1 to 3), aluminum molybdate, silicon molybdate, magnesium molybdate, sodium molybdate, titanium molybdate, iron molybdate, potassium molybdate, zinc molybdate, boron molybdate, lithium molybdate, cobalt molybdate, nickel molybdate, manganese molybdate, chromium molybdate, cesium molybdate, barium molybdate, strontium molybdate, yttrium molybdate, zirconium molybdate, and copper molybdate.

For the tungsten compounds, examples include, although not particularly restricted, tungsten trioxide, tungsten sulfide, tungstic acid, tungsten chloride, calcium tungstate, potassium tungstate, lithium tungstate, aluminum tungstate, tungsten sodium, ammonium paratungstate, ammonium metatungstate, phosphotungstic acid, and silicotungstic acid.

For the vanadium compounds, examples include, although not particularly restricted, vanadium oxide, ammonium metavanadate, potassium vanadate, sodium metavanadate, sodium vanadate, vanadium oxychloride, vanadium oxysulfate, and vanadium chloride.

For the chlorine compounds, examples include, although not particularly restricted, potassium chloride, sodium chloride, lithium chloride, magnesium chloride, barium chloride, and ammonium chloride.

For the fluorine compounds, examples include, although not particularly restricted, aluminum fluoride, sodium fluoride, magnesium fluoride, calcium fluoride, cryolite, and lead fluoride.

For the boron compounds, examples include, although not particularly restricted, boric acid, boron oxide, sodium borate, and boron fluoride.

For the sulfates, examples include, although not particularly restricted, sodium sulfate, potassium sulfate, calcium sulfate, and lithium sulfate.

For the nitrates, examples include, although not particularly restricted, sodium nitrate, potassium nitrate, calcium nitrate, and lithium nitrate.

For the carbonates, examples include, although not particularly restricted, sodium carbonate, potassium carbonate, calcium carbonate, and lithium carbonate.

One such flux may be used alone, or two or more may be used in combination.

Of these, it is preferred that the flux include molybdenum compounds because this facilitates the formation of a single-crystal structure in the resulting metal oxide and/or the control of the shape of the metal oxide. More preferably, the flux includes molybdenum trioxide because this allows for efficient collection when the vaporized flux is converted into powder.

The amount of flux used is not particularly restricted and can be selected as appropriate according to the desired metal oxide. For example, when a metal oxide with a large particle diameter (1 mm or more) is manufactured, it is preferred that the molar ratio of the flux metal constituting the flux to the metal element constituting the metal compound, which will be described below, exceed 3.0 (flux metal/metal element). When a metal oxide with a small particle diameter (less than 1 mm) is manufactured, by contrast, it is preferred that the molar ratio of the flux metal constituting the flux to the metal element constituting the metal compound, which will be described below, be from 0.001 to 3.0 moles (flux metal/metal element), more preferably from 0.03 to 3.0, even more preferably from 0.08 to 0.7.

### Metal Compound

Examples of metal compounds include, although not particularly restricted, aluminum compounds, silicon compounds, titanium compounds, magnesium compounds, sodium compounds, potassium compounds, zirconium compounds, yttrium compounds, zinc compounds, copper compounds, and iron compounds. Of these, the use of an aluminum compound, silicon compound, titanium compound, or magnesium compound is preferred.

For the aluminum compound, examples include aluminum chloride, aluminum sulfate, basic aluminum acetate, aluminum hydroxide, boehmite, pseudoboehmite, transition aluminas (e.g., γ-alumina, δ-alumina, and θ-alumina), α-alumina, and mixed aluminas, which have two or more types of crystal phases.

For the silicon compound, examples include crystalline silica, forms of artificially synthesized amorphous silica, such as silica gel, silica nanoparticles, and mesoporous silica, organic silicon compounds, which contain silicon, and biosilica.

For the titanium compound, examples include, although not particularly restricted, titanium chloride, titanium sulfate, metatitanic acid, amorphous titanium oxide, anatase-type titanium oxide, rutile-type titanium oxide, and anatase-rutile mixed titanium oxides.

For the magnesium compound, examples include, although not particularly restricted, magnesium oxide, magnesium hydroxide, magnesium acetate tetrahydrate, magnesium carbonate, magnesium sulfate, magnesium chloride, magnesium nitride, magnesium hydride, magnesium fluoride, magnesium iodide, magnesium bromide, magnesium acrylate, magnesium dimethacrylate, magnesium ethoxide, magnesium gluconate, magnesium naphthenate, magnesium salicylate tetrahydrate, magnesium stearate, magnesium molybdate, magnesium lactate trihydrate, magnesium potassium chloride, magnesium nitrate hexahydrate, magnesium bromide hexahydrate, magnesium chloride hexahydrate, magnesium sulfate heptahydrate, magnesium oxalate dihydrate, magnesium benzoate tetrahydrate, magnesium citrate n-hydrates, trimagnesium dicitrate nonahydrate, and magnesium monoperoxyphthalate.

One such metal compound may be used alone, or two or more may be used in combination.

It should be noted that when two or more metal compounds are used in combination, the manufactured oxide can be a composite oxide. For example, when an aluminum compound and a magnesium compound are used in combination, it is possible to manufacture a spinel composite oxide having a basic composition of MgAl₂O₄.

Of these, the use of an aluminum compound or an aluminum compound and a magnesium compound is preferred.

### Step (2)

In step (2), the reactants (the metal compound and the flux) or the product (the metal oxide obtained through the reaction between the metal compound and the flux) is transported inside the firing furnace from a point closer to one of the first gas inlet (gas inlet) or gas outlet to a point closer to the other. For instance, in the example in FIG. 2, the reactants or product is transported inside the firing furnace 10 from a point closer to the gas outlet 30 to a point closer to the first gas inlet 20. The form of transport is not particularly restricted as long as the reactants or product can be continuously transported in a predetermined direction within the firing furnace. For example, however, the reactants or product may be transported by placing the reactants or product in multiple containers and sequentially moving the containers inside the furnace. The rate of transport of the reactants or product, furthermore, is not particularly restricted as long as a period of time is allowed for the metal compound and the flux to react adequately inside the firing furnace.

### Step (3)

In step (3), in the firing furnace, a heating region is defined closer to one of the gas outlet or first gas inlet (gas inlet), a cooling region is defined closer to the other of the gas outlet or first gas inlet, and a reaction region is defined between the heating region and the cooling region, with the reaction region being a region in which the temperature is higher than in both of the heating region and the cooling region and in which the metal compound and the flux react, and with the use of airflow generated by the gas introduced through the first gas inlet, furthermore, the flux vaporized in the reaction region is converted into powder in the heating region or the cooling region, and gas containing the powder of the flux is delivered to the gas outlet. For instance, in the example in FIG. 2, a heating region 12A is defined closer to the gas outlet 30, a cooling region 14A is defined closer to the first gas inlet 20, and a reaction region 13A is defined between the heating region 12A and the cooling region 14A, with the reaction region 13A being a region in which the temperature is higher than in both of the heating region 12A and the cooling region 14A and in which the metal compound and the flux react. With the use of airflow AF1 generated by the gas introduced through the first gas inlet 20, furthermore, the flux vaporized in the reaction region 13A is converted into powder in the heating region 12A, and gas containing the powder of the flux is delivered to the gas outlet 30.

In the heating region, the metal compound is heated in the presence of the flux for easier evaporation of the flux in the downstream reaction region. In the example in FIG. 2, moreover, while the metal compound and the flux are heated in the heating region 12A, the vaporized flux is converted there into powder through the cooling of gas containing it.

The temperature in the heating region is not particularly restricted, but preferably is from 20° C. to 2000° C., more preferably from 40° C. to 1500° C.

In the heating region, it is preferred that the rate of heating of the metal compound and the flux be from 0.5° C./minute to 100° C./minute for manufacturing efficiency reasons, although the range varies depending partly on factors such as the flux and metal compound used and the desired metal oxide. More preferably, the rate of heating is from 1° C./minute to 50° C./minute, even more preferably from 2° C./minute to 10° C./minute. Specifically, the temperature gradient (° C./m) and the rate of transport (m/s) in the heating region within the firing furnace can be set, and a rate of heating falling inside the above ranges can be achieved based on the set temperature gradient and rate of transport.

### Cooling of the Vaporized Flux

The cooling of the vaporized flux is conducted by utilizing the temperature difference between the heating region and the reaction region.

The rate of cooling of the vaporized flux is not particularly restricted, but preferably is from 100° C./second to 100000° C./second, more preferably from 1000° C./second to 50000° C./second. Incidentally, with faster rates of cooling of the flux, a powder of the flux with smaller particle diameters and larger specific surface areas tends to be obtained.

The rate of discharge of the powder of the flux from the firing furnace to the gas outlet can be controlled by the amount of flux used, the temperature of the firing furnace, the blowing of the gas into the firing furnace, and the caliber of the firing furnace vent. The rate of discharge of the powder of the flux from the firing furnace to the gas outlet is preferably from 0.001 to 100 g/minute, more preferably from 0.1 to 50 g/minute, per kg of the raw-material metal compound.

By supplying gas into the gas outlet from the outside, furthermore, the gas containing the powder of the flux may be discharged out of the furnace. For instance, in the example in FIG. 2, the main duct 31 of the gas outlet 30 discharges the gas inside the firing furnace 10 containing the powder of the flux out of the furnace, and the third gas inlet 32, provided to the main duct 31, supplies gas from the outside to the gas that flows through the main duct 31.

In addition, the velocity of gas blowing and the in-pipe flow rate in the gas outlet can be regulated with a throttle damper, not illustrated, as needed.

In the reaction region, the metal compound is fired at a high temperature in the presence of the flux, and a metal oxide is manufactured by evaporating the flux (flux evaporation method).

In flux evaporation method, it is customary that the flux and the metal compound first react to form an intermediate. Then the intermediate is decomposed, and its crystals are allowed to grow. As a result, a metal oxide can be manufactured. During this, the growth of the metal oxide crystals is promoted by the evaporation of the flux as a driving force.

It should be noted that when the flux used is a molybdenum compound, for example, the reactants form a metal molybdate as an intermediate. This molybdate decomposes, resulting in the manufacture of a metal oxide. During this, molybdenum trioxide evaporates through vaporization, and the growth of the metal oxide crystals is promoted by the evaporation as a driving force.

The state of mixing between the flux and the metal oxide is not particularly limited; the flux and the metal compound only need to be present in the same space. Even when the two materials are not mixed, for example, the flux reaction can proceed. When the two materials are mixed, methods such as simple mixing, in which powders are mixed together, mechanical mixing using a mill or other equipment, and mixing using a mortar or similar tools can be carried out. In that case, the resulting mixture may be in either a dry state or wet state. When the two materials are in a state in which they are not mixed, the firing temperature is set equal to or higher than the sublimation temperature of the flux. This causes the vaporized flux to make contact with the metal oxide, allowing a gas-solid reaction to be conducted.

As for the firing temperature, it is usually preferred to set it to a temperature at which the intermediate decomposes, although the temperature varies depending partly on factors such as the flux and metal compound used and the desired metal oxide. For example, when the flux used is a molybdenum compound with the metal compound used being an aluminum compound, the firing temperature is preferably from 500° C. to 900° C. because the intermediate formed can be aluminum molybdate. More preferably, the firing temperature is from 600° C. to 900° C., even more preferably from 700° C. to 900° C.

For the duration of the reaction, too, there is no specific restriction on it. For example, the duration of the reaction can be from 1 minute to 30 hours.

### Vaporized Flux

The vaporized flux varies with the flux used, but usually is the metal oxide that constitutes the flux. For example, when the flux used is ammonium molybdate, it is transformed into molybdenum trioxide, which is thermodynamically stable, through firing. The flux that vaporizes, therefore, is the molybdenum trioxide. It should be noted that in certain types of flux evaporation method, the flux and the metal compound form an intermediate. Even in that case, the flux vaporizes in a thermodynamically stable form because the intermediate decomposes through firing before crystal growth.

The temperature of the vaporized flux is preferably from 200° C. to 2000° C., although the range varies depending partly on the type of flux used. More preferably, the temperature is from 400° C. to 1500° C. Incidentally, when the temperature of the vaporized flux is 2000° C. or below, the conversion of the vaporized flux into powder in the cooling region usually tends to be easy.

In the cooling region, the metal oxide obtained through the reaction between the metal compound and the flux is cooled. In the example in FIG. 2, moreover, the cooling of the resulting metal oxide in the cooling region 14A takes place simultaneously with the heating of the gas introduced through the first gas inlet 20.

The temperature in the cooling region is not particularly restricted, but preferably is from 20° C. to 2000° C., more preferably from 40° C. to 1500° C.

In the cooling region, it is preferred that the rate of cooling of the metal oxide be from 0.1° C./minute to 100° C./minute for manufacturing efficiency reasons, although the range varies depending partly on factors such as the flux and metal compound used and the desired metal oxide. More preferably, the rate of cooling is from 1° C./minute to 50° C./minute, even more preferably from 2° C./minute to 20° C./minute.

### Metal Oxide

The metal oxide varies with factors such as the metal compound used. For the functionality of the metal oxide, however, it is preferred that the metal oxide be aluminum oxide, silicon oxide, titanium oxide, magnesium oxide, sodium oxide, potassium oxide, zirconium oxide, yttrium oxide, zinc oxide, copper oxide, iron oxide, or an aluminum-magnesium spinel composite oxide. More preferably, the metal oxide is aluminum oxide, silicon oxide, titanium oxide, or an aluminum-magnesium spinel composite oxide, even more preferably aluminum oxide or an aluminum-magnesium spinel composite oxide.

As for the crystal structure and other details of the metal oxide, the metal oxide usually can have a dense single-crystal structure because it is manufactured by flux evaporation method. A metal oxide having such a dense single-crystal structure can possess high functionality. For example, aluminum oxide and aluminum-magnesium spinel composite oxides intrinsically tend to be of low density and have a polycrystalline structure. These oxides, therefore, are prone to cause phonon scattering; with these oxides, it is difficult to achieve a high thermal conductivity. Aluminum oxide and aluminum-magnesium spinel composite oxides obtained through flux evaporation method, however, have a dense and highly ordered crystal structure. With these oxides, therefore, phonon scattering is reduced, and it is possible to achieve a high thermal conductivity. Such a crystal structure and other details can be controlled as needed by parameters such as the type and amount of flux used, the type and amount of metal compound used, and the firing conditions in flux evaporation method.

Incidentally, the metal oxide can contain the flux. For example, when the flux used is a molybdenum compound, it mostly evaporates in forms such as molybdenum trioxide as mentioned earlier herein. Part of the molybdenum compound, however, is taken into the metal oxide. As a result, the aluminum oxide, containing molybdenum, can be a colored one.

The amount of flux in the metal oxide is not particularly restricted. For efficient manufacturing of the metal oxide at low cost, however, it is preferred that the flux content be 10% by mass or less, more preferably 5% by mass or less, even more preferably 3% to 0.01% by mass. It is worth noting that when a metal oxide manufactured by the flux method contains a flux, the flux content tends to be greater than those of metal elements contained as inevitable impurities (usually around 100 ppm).

The average particle diameter of the metal oxide is not particularly restricted, but preferably is from 0.1 to 1000 μm, more preferably from 0.2 to 100 μm, even more preferably from 0.3 to 80 μm, particularly preferably from 0.4 to 60 μm. In the present description, an “average particle diameter” refers to a value calculated from the diameters of 100 randomly selected particles measured in their images obtained using a scanning electron microscope (SEM). In this context, the “diameter” of a particle refers to the largest length of the distances between two points on the outline of the particle.

The shape of the metal oxide can be controlled by changing the manufacturing conditions as needed according to purposes. For example, when the manufacture of α-phase aluminum oxide is attempted using molybdenum oxide as the flux and aluminum oxide as the metal compound, the α-phase aluminum oxide can be manufactured by changing the amount of flux added and the firing conditions as necessary.

In an embodiment, using a large amount of molybdenum oxide and allowing for slow crystal growth over an extended period leads to the manufacture of hexagonal-bipyramidal α-phase aluminum oxide. Such a form of α-phase aluminum oxide can be utilized in applications such as lasing materials, high-hardness bearing materials, standard materials for characteristics measurement, and jewelry.

In another embodiment, furthermore, using a small amount of molybdenum oxide and allowing for crystal growth over a short period leads to the manufacture of single-crystal α-phase aluminum oxide, which has a single-crystal structure and a narrow particle diameter distribution. Such a form of α-phase aluminum oxide can be utilized in applications such as resin fillers, abrasives, and raw materials for fine ceramics.

In both of these cases, molybdenum oxide can

selectively adsorb onto the plane of the aluminum oxide crystals. As a result, the crystal component is less likely to be supplied to the plane, helping reduce the appearance of the plane. Consequently, a-phase aluminum oxide with a non-[001] plane as its main crystallographic plane can be manufactured. Unlike sheet-shaped α-aluminum oxide or polyhedrons with the plane as their main crystallographic plane obtained through ordinary firing, α-phase aluminum oxide having such a crystal structure exhibits an efficient inhibition of the growth of its crystallographic plane and can form well-proportioned particles in a nearly spherical polyhedral shape. As used herein, being “with a non-[001] plane as its main crystallographic phase” means that the area of the plane is 20% or less of the total area in the metal oxide.

In addition, when the metal oxide is a spinel composite oxide having a basic composition of MgAl₂O₄, polyhedral particles having a single-crystal structure can be manufactured. Such spinel particles can be utilized in applications such as resin fillers, catalysts, optical materials, raw materials for substrates, and abrasives.

When being rutile-type titanium oxide, furthermore, the metal oxide can be utilized in applications such as paints, inks, and cosmetics by virtue of having superior masking properties and high infrared scattering capability. Moreover, when the metal oxide is silicon oxide, a two-phase bicontinuous structure composed of Q4 bonds and substantially free of silanol groups can be manufactured, which can be utilized in applications such as carriers in life science and resin fillers, catalysts, and cosmetics.

After the above step (3), the method may include step (4), the collection of the powder of the flux.

In step (4), the powder of the flux contained in the gas sent out from the gas outlet is collected, for example using a dust collector. Alternatively, the powder of the flux contained in the gas sent out from the gas outlet may be classified, for example using a classifier, and the classified flux may be collected.

The method for collecting the flux is not particularly restricted; it may be batch collection or continuous collection.

When batch collection is used, the powder of the flux is collected from the collecting means after each reaction. In this case, shape control, for example, for the metal oxide can be conducted in a suitable manner by adjusting parameters such as the amount added and particle diameter of the collected flux before using it for the manufacture of the metal oxide.

Moreover, when continuous collection is used, the powder of the flux is collected consecutively while the reaction is ongoing. In this case, the flux can be directly and continuously mixed with the metal compound and loaded into the firing furnace, leading to potential advantages such as increased production of the metal oxide in unit time.

After the above step (4), furthermore, the method may further include, for example, step (4), the reuse of the flux collected in step (3).

The flux collected in step (4) is one obtained by converting a vapor into powder and tends to be of high purity. This flux, therefore, can be reused again for the manufacture of the metal oxide. As a result of this, environmental impact can be reduced, and, furthermore, the manufacturing cost can be lowered.

As stated above, according to this embodiment, the flux vaporized in the reaction region 13A is converted into powder in the heating region 12A, in which the temperature is lower than in the reaction region 13A, and gas containing the powder of the flux is delivered to the gas outlet 30, both with the use of airflow AF1 generated by the gas introduced through the first gas inlet 20. The flux in the airflow AF1, therefore, transitions from gas to solid in the heating region 12A within the firing furnace 10, and the vaporized flux is scarcely delivered to the gas outlet 30. By virtue of this, the flux can be collected in a stable manner, and, furthermore, the adhesion of the flux at the gas outlet 30 can be prevented. No installation of jigs for removing an adhering flux or components for preventing the reaction between the gas outlet 30 and the flux, such as a heat-insulating sleeve, is required, helping reduce maintenance efforts much more.

In addition, the airflow AF1 is countercurrent with respect to the direction of transport by the transport device 40. It passes through the cooling region 14A, reaction region 13A, and heating region 12A in this order and converts the flux vaporized in the reaction region 13A into powder in the heating region 12A. This leads to efficient cooling of the container 41 and the product in the container 41 by airflow AF1 at a relatively low temperature in the cooling region 14A and efficient heating of the container 41 and the reactants in the container 41 by airflow AF1 at a relatively high temperature in the heating region 12A. As a result, effective thermal energy utilization can be achieved through heat exchange between the gas constituting the airflow AF1 and the container 41 and the reactants or product in the container 41, helping seek energy conservation while collecting the flux in a stable manner.

FIG. 3 is a schematic view illustrating a variation of a metal oxide manufacturing device according to this embodiment.

As illustrated in FIG. 3, the metal oxide manufacturing device 1B includes a firing furnace 10 that fires at least metal compound in the presence of at least one flux, at least one first gas inlet 20 that is disposed closer to a first end 10b of the firing furnace 10 and introduces gas into the firing furnace 10, a gas outlet 30 that is disposed closer to a second end 10a of the firing furnace 10 and discharges gas inside the firing furnace 10 to the outside, and a transport device 40 that is placed inside the firing furnace 10 and transports the metal compound and the flux or a metal oxide obtained through the reaction therebetween from a point closer to the first gas inlet 20 to a point closer to the gas outlet 30.

The firing furnace 10 has a heating region 12B defined closer to the first gas inlet 20, a cooling region 14B defined closer to the gas outlet 30, and a reaction region 13B that is defined between the heating region 12B and the cooling region 14B, in which the temperature is higher than in both of the heating region 12B and the cooling region 14B, and in which the metal compound and the flux react.

In this variation, the heating region 12B has been defined closer to the first end 10b of the firing furnace 10, and the cooling region 14B has been defined closer to the second end 10a of the firing furnace 10. The container 41, furthermore, passes through the heating region 12B, reaction region 13B, and cooling region 14B inside the firing furnace 10 and is transported in this order.

For this metal oxide manufacturing device 1B, the transport device 40 has been placed inside the firing furnace 10 and transports the metal compound and the flux or a metal oxide obtained through the reaction therebetween from a point closer to the first gas inlet 20 to a point closer to the gas outlet 30.

The metal oxide manufacturing device 1B utilizes airflow AF2 generated by the gas introduced through the first gas inlet 20 to convert the flux vaporized in the reaction region 13A into powder in the cooling region 14A and to deliver gas containing the powder of the flux powder to the gas outlet 30. In this variation, the airflow AF2 is co-current with respect to the direction of transport by the transport device 40 and passes through the heating region 12B, reaction region 13B, and cooling region 14B in this order. Additionally, the airflow AF2 converts the flux vaporized in the reaction region 13B into powder in the cooling region 14B. In this embodiment, therefore, the cooling region 14B functions as a region in which the metal oxide, which is the product, is cooled and in which the flux is converted into powder through the cooling of gas containing the vaporized flux at the same time. In the example in FIG. 3, the vaporized flux is converted into powder at a point P2 that is on the airflow AF2 and above the transport device 40 (upper portion of the cooling region 14B).

By virtue of the airflow AF2 being co-current with respect to the direction of transport by the transport device 40, furthermore, a vapor of the flux obtained from the metal compound and the flux that are transported by the transport device 40 and located in an upstream portion 13Ba, with respect to the direction of transport, of the reaction region 13B can be supplied to the metal compound and the flux located in a downstream portion 13Bb of the reaction region 13B. Even when the reaction between the metal compound and the flux is not adequate in the downstream portion 13Bb because of a reduced amount of flux, therefore, the flux can be supplied to the metal compound located in the downstream portion 13Bb to ensure an adequate rection between the metal compound and the flux and, furthermore, to increase the rate of reaction between the metal compound and the flux.

According to this variation, the flux vaporized in the reaction region 13A is converted into powder in the cooling region 14B, in which the temperature is lower than in the reaction region 13B, and gas containing the powder of the flux is delivered to the gas outlet 30, both with the use of airflow AF2 generated by the gas introduced through the first gas inlet 20. The flux in the airflow AF2, therefore, transitions from gas to solid in the cooling region 14B within the firing furnace 10, and the vaporized flux is scarcely delivered to the gas outlet 30. By virtue of this, the flux can be collected in a stable manner, and, furthermore, the adhesion of the flux at the gas outlet 30 can be prevented. No installation of jigs for removing an adhering flux or components for preventing the reaction between the gas outlet 30 and the flux, such as a heat-insulating sleeve, is required, helping reduce maintenance efforts much more.

Moreover, a vapor of the flux obtained from the metal compound and the flux located in an upstream portion 13Ba of the reaction region 13B is supplied to the metal compound located in a downstream portion 13Bb of the reaction region 13B, helping ensure an adequate reaction between the metal compound and the flux. As a result, particles of the metal oxide obtained as the reactant, such as aluminum oxide, are more likely to be sheet-shaped; the formation of sheet-shaped particles can be encouraged.

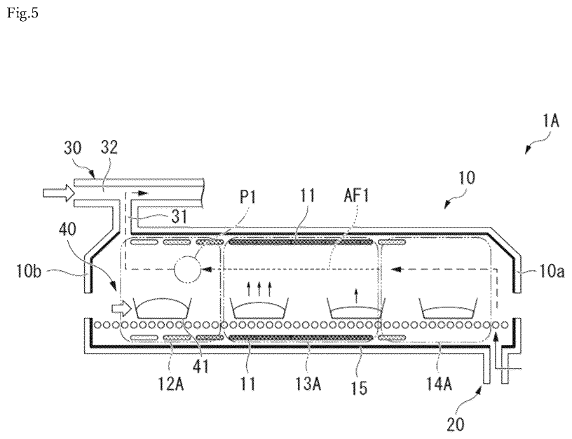

FIG. 4 is a schematic view illustrating another variation of a metal oxide manufacturing device according to this embodiment. As illustrated in FIG. 4, the metal oxide manufacturing device 1C further includes a second gas inlet 50 that is disposed at the cooling region 14B in the firing furnace 10 and supplies gas to the airflow AF2 that passes through the cooling region 14B.

The second gas inlet 50 is created in, for example, the top wall of the firing furnace 10. For better cooling of the airflow AF2, it is preferred that the second gas inlet 50 be positioned immediately above the cooling region 14B, more preferably immediately above the point P2, at which the conversion of the flux into powder is ongoing. In this variation, furthermore, the gas coming through the second gas inlet 50 is supplied from above the airflow AF2 and collides with the airflow AF2 at right angles. The gas, however, may be allowed to collide at another angle, such as an acute angle, unless it affects the direction of the airflow AF2.

The second gas inlet 50 may have been created somewhere other than the top wall of the firing furnace 10, such as the bottom or a side wall of the firing furnace 10, as long as the airflow AF2 can be cooled in the cooling region 14B.

The gas introduced through the second gas inlet 50 is not particularly restricted as long as it has no reactivity with the flux vapor, but examples include air (in that case, a gas intake port is herein also referred to as an “external air intake port” in particular), oxygen, nitrogen, argon, and steam. Of these, it is preferred that the gas be air for cost reasons.

The temperature of the gas introduced through the second gas inlet 50 is preferably from 5° C. to 100° C., more preferably from 5° C. to 40° C.

The rate of blowing of the gas introduced through the second gas inlet 50 is not particularly restricted, but preferably is from 1 to 500 L/min, more preferably from 10to 200 L/min, per 100 L of the effective volume of the firing furnace 10.

The second gas inlet 50 may include a second blowing device, not illustrated, that forces air into the firing furnace 10 and a cooling device, not illustrated, that cools the air sent into the firing furnace 10. This enables further cooling of the airflow AF2. The second gas inlet 50, furthermore, may include a throttle damper, not illustrated, that regulates the quantity, velocity, etc., of the gas introduced into the firing furnace.

According to this variation, gas is supplied to the airflow AF2 that passes through the cooling region 14B by virtue of the second gas inlet 50. The cooling of the airflow AF2, therefore, is encouraged in the cooling region 14B, and particles of the flux with uniform diameters and little or reduced aggregation therebetween can be collected in a more stable manner. By making the temperature of the gas introduced through the second gas inlet 50 lower, furthermore, large-diameter particles of the flux with uniform diameters and further reduced aggregation therebetween can be collected.

FIG. 5 is a schematic view illustrating another variation of a metal oxide manufacturing device according to this embodiment. As illustrated in FIG. 5, the firing furnace 10 may include an anticorrosive heat insulator 15 attached to the inner surface of the firing furnace 10. The heat insulator 15 is provided to at least part of the inner surface of the bottom wall, side walls, or top wall of the firing furnace 10, but preferably is attached to the inner surface of the bottom wall, side walls, and top wall.

The material for the heat insulator 15 is not particularly restricted as long as it has corrosion resistance in addition to the prerequisite heat-insulating properties and heat resistance, but an example is glass wool. When resistance to corrosion by molybdenum oxide and other fluxes is considered, materials such as alumina fiber, clay brick, and high-alumina brick are preferred.

According to this variation, an anticorrosive heat insulator 15 is attached to the inner surface of the firing furnace 10. Thermal efficiency, therefore, improves owing to controlled heat radiation from the firing furnace 10. At the same time, corrosion-induced degradation of the firing furnace 10 can be mitigated, helping further reduce maintenance efforts.

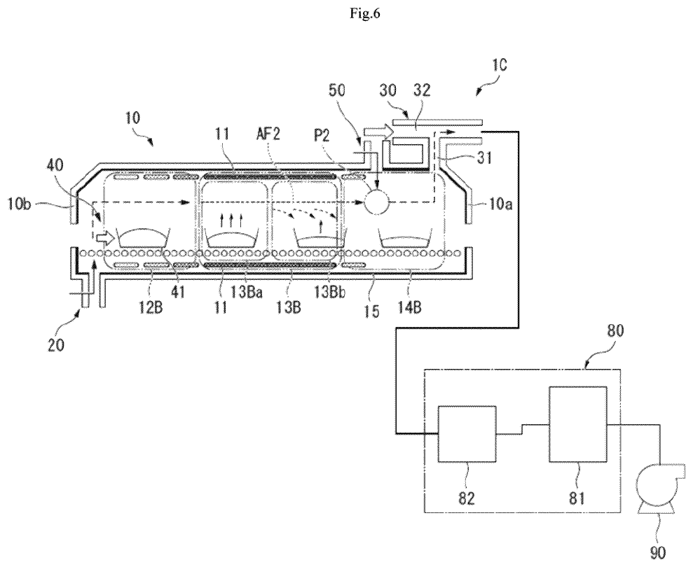

FIG. 6 is a schematic view illustrating another variation of a metal oxide manufacturing device according to this embodiment. As illustrated in FIG. 6, the metal oxide manufacturing device 1C includes a collection device 80 that is coupled to the gas outlet 30 and collects the powder of the flux contained in the gas. The collection device 80 includes a dust collector 81 that collects the powder of the flux and a classifier 82 that is disposed between the gas outlet 30 and the dust collector 81 and classifies the powder of the flux. Although the collection device 80 in this variation includes a dust collector 81 and a classifier 82, this is not the only possible configuration; the collection device 80 may lack a classifier 82. In that case, the dust collector 81 is directly coupled to the gas outlet 30 of the firing furnace 10.

The dust collector 81 collects the flux converted into powder in the cooling region 14B within the firing furnace 10. Examples for the dust collector 81 include, although not particularly restricted, a cyclone dust collector, a bag-filter dust collector, an inertial dust collector, a moving-bed dust collector, a wet dust collector, a filter dust collector, and an electric dust collector.

The classifier 82 segregates the flux converted into powder in the cooling region 14B within the firing furnace 10 based on particle size (particle diameter). As a result of this, flux particles falling within a predetermined range of sizes (particle diameters) are delivered to the dust collector 81. The classifier 82 is not particularly restricted, but an example is a dry classifier. The dry classifier can be, for instance, a centrifugal weight-based classifier, such as a cyclone classifier, gravity classifier, or inertial classifier.

To the collection device 80, an exhaust device 90 as a third blowing device is coupled. As a result of air expulsion by the exhaust device 90, the inside of the dust collector 81, classifier 82, and gas outlet 30 is aspirated, causing external air to be sent to the gas outlet 30 through the third gas inlet 32 that the gas outlet 30 has. In other words, as a result of aspiration by the exhaust device 90, a passive air blow into the gas outlet 30 occurs.

According to this variation, a dust collector 81 collects the flux converted into powder in the cooling region 14B within the firing furnace 10. The collected flux, therefore, can be recycled for the manufacture of the metal oxide. As a result, environmental impact can be reduced, and the manufacturing cost can be lowered. A classifier 82, furthermore, classifies the powder of the flux, thereby allowing for the collection of flux particles falling within a predetermined range of sizes (e.g., relatively large-diameter particles) at the dust collector 81 placed downstream. As a result, the collected flux can be directly utilized for recycling, and flux particles falling outside the predetermined range of sizes (e.g., relatively small-diameter particles) can be separately collected and used in other applications. Sorting out flux particles with similar diameters also makes it easier to perform the control of, for example, the formation of a sheet-shaped metal oxide.

This embodiment has been described hereinabove. The present invention, however, is not necessarily limited to those in the above embodiment; various modifications can be made within the spirit of the present invention.

### Reference Signs List

1A Manufacturing device
1B Manufacturing device
1C Manufacturing device
10 Firing furnace
10a First end (second end)
10b Second end (first end)
11 Heater
12A Heating region
12B Heating region
13A Reaction region
13B Reaction region
13Ba Upstream portion
13Bb Downstream portion
14A Cooling region
14B Cooling region
15 Heat insulator
20 First gas inlet
30 Gas outlet
31 Main duct
32 Third gas inlet
40 Transport device
41 Container
50 Second gas inlet
80 Collection device
81 Dust collector
82 Classifier
90 Exhaust device

1. A device for manufacturing a metal oxide by flux evaporation method, the device comprising:
a firing furnace that fires a metal compound in presence of a flux;
a first gas inlet that is disposed closer to a first end of the firing furnace and introduces gas into the firing furnace;
a gas outlet that is disposed closer to a second end of the firing furnace and discharges gas inside the firing furnace to outside; and
a transport device that is placed inside the firing furnace and transports the metal compound and the flux or a metal oxide obtained through reaction therebetween from a point closer to one of the first gas inlet or the gas outlet to a point closer to the other, wherein:
the firing furnace has a heating region defined closer to one of the gas outlet or the first gas inlet, a cooling region defined closer to the other of the gas outlet or the first gas inlet, and a reaction region that is defined between the heating region and the cooling region, in which temperature is higher than in both of the heating region and the cooling region, and in which the metal compound and the flux react; and
with use of airflow generated by the gas introduced through the first gas inlet, the flux vaporized in the reaction region is converted into powder in the heating region or the cooling region, and gas containing the powder of the flux is delivered to the gas outlet.

2. The device according to claim 1 for manufacturing a metal oxide, wherein:
the heating region is defined closer to the gas outlet, and the cooling region is defined closer to the first gas inlet;
the airflow is countercurrent with respect to a direction of transport by the transport device and passes through the cooling region, the reaction region, and the heating region in this order; and
the flux vaporized in the reaction region is converted into powder in the heating region.

3. The device according to claim 1 for manufacturing a metal oxide, wherein:
the heating region is defined closer to the first gas inlet, and the cooling region is defined closer to the gas outlet;
the airflow is co-current with respect to a direction of transport by the transport device and passes through the heating region, the reaction region, and the cooling region in this order; and
the flux vaporized in the reaction region is converted into powder in the cooling region.

4. The device according to claim 3 for manufacturing a metal oxide, wherein a vapor of the flux obtained from the metal compound and the flux located upstream of the reaction region with respect to the direction of transport, out of the metal compound and the flux transported by the transport device, is supplied to the metal compound and the flux located downstream of the reaction region.

5. The device according to claim 3 for manufacturing a metal oxide, further comprising a second gas inlet that is disposed at the cooling region in the firing furnace and supplies gas to the airflow that passes through the cooling region.

6. The device according to claim 1 for manufacturing a metal oxide, wherein the gas outlet includes a main duct through which the gas inside the firing furnace is discharged out of the furnace and a third gas inlet that is provided to the main duct and through which gas is supplied from outside to the gas containing the powder of the flux that flows through the main duct.

7. The device according to claim 1 for manufacturing a metal oxide, wherein the firing furnace includes an anticorrosive heat insulator attached to an inner surface of the firing furnace.

8. The device according to claim 1 for manufacturing a metal oxide, comprising a collection device that is coupled to the gas outlet and collects the powder of the flux contained in the gas.

9. The device according to claim 8 for manufacturing a metal oxide, wherein the collection device includes a dust collector that collects the powder of the flux.

10. The device according to claim 9 for manufacturing a metal oxide, wherein the collection device further includes a classifier that is disposed between the gas outlet and the dust collector and classifies the powder of the flux.

11. A method for manufacturing a metal oxide by flux evaporation method, the method comprising:
introducing gas into a firing furnace, the firing furnace configured to fire a metal compound in presence of a flux, through a gas inlet disposed closer to a first end of the firing furnace and discharging gas inside the firing furnace to outside through a gas outlet disposed closer to a second end of the firing furnace;
transporting, inside the firing furnace, the metal compound and the flux or a metal oxide obtained through reaction therebetween from a point closer to one of the gas inlet or the gas outlet to a point closer to the other; and
defining, in the firing furnace, a heating region closer to one of the gas outlet or the gas inlet, a cooling region closer to the other of the gas outlet or the gas inlet, and a reaction region between the heating region and the cooling region, with the reaction region being a region in which temperature is higher than in both of the heating region and the cooling region and in which the metal compound and the flux react, and, with use of airflow generated by the gas introduced through the gas inlet, converting the flux vaporized in the reaction region into powder in the heating region or the cooling region and delivering gas containing the powder of the flux to the gas outlet.
